(19) United States
(12) Patent Application Publication
(10) Pub. No.: US 2013/0193954 A1
(43) Pub. Date: Aug. 1, 2013

(54) CURRENT DETECTING DEVICE

(71) Applicants: Hirokatsu Nakajima, Mie (JP); Satoru Chaen, Mie (JP)

(72) Inventors: Hirokatsu Nakajima, Mie (JP); Satoru Chaen, Mie (JP)

(73) Assignee: SUMITOMO WIRING SYSTEMS, LTD., Yokkaichi-shi, Mie (JP)

(21) Appl. No.: 13/876,275

(22) PCT Filed: Jul. 25, 2011
(86) PCT No.: PCT/JP2011/066844

§ 371 Date: Mar. 27, 2013

(30) Foreign Application Priority Data
Dec. 27, 2010 (JP) 2010-289565

(51) Int. Cl. G01R 19/00

(52) U.S. Cl. CPC G01R 19/0092
USPC 324/117 R

(57) ABSTRACT

A current detecting device is readily attached to a wire while preventing variation in current detection accuracy. A current detecting device has a core module and an element module, the core module having a core support that supports a magnetic core, the element module having an element support that supports a Hall element therein. In a position of a gap of the magnetic core in the core module, a wire insertion path is provided, to which the element support is fitted. Two end portions of the magnetic core and the Hall element are positioned by first and second contact surfaces of the core support and by a third contact surface of the element support. The two modules are connected so as to be movable relative to each other and are fixated by a lock mechanism in a state where the element support is fitted to the wire insertion path.

### TECHNICAL FIELD

The present invention relates to a current detecting device that detects a current flowing through a wire.

### BACKGROUND ART

Automobiles such as hybrid or electric vehicles are often equipped with a current detecting device that detects a current flowing through a wire, such as a bus bar or a covered wire, connected to a battery. Such a current detecting device sometimes employs a magnetic proportion system or a magnetic balance system. In the present specification, a wire represents a conductive body that forms a current transmission path, including a covered wire and a bus bar.

The current detecting device of the magnetic proportion system or the magnetic balance system includes a magnetic core and a magnetoelectric transducer (magnetic sensing element), as disclosed in Patent Literature 1, for example. The magnetic core is a continuously formed, substantially ring-shaped magnetic body having two ends opposite to each other with a gap therebetween and surrounding a hollow portion through which a wire is inserted. The hollow portion of the magnetic core is a space through which a current to be detected passes.

The electromagnetic transducer, which is disposed in the gap of the magnetic core, detects a magnetic flux that varies in response to the current flowing through the wire inserted through the hollow portion, and then outputs a magnetic flux detection signal as an electric signal. Normally, a Hall element is employed for the magnetoelectric transducer.

In a case where the magnetoelectric transducer is misaligned from an ideal position relative to the two end portions of the magnetic core, current detection sensitivity of the current detecting device varies substantially. Thus, it is important to position the two end portions of the magnetic core and the magnetoelectric transducer with a high level of accuracy in the current detecting device in order to achieve both a reduction in device size and consistency in quality.

As disclosed in Patent Literature 1, the magnetic core and the magnetoelectric transducer are often held in a predetermined positional relationship by an insulating casing in the current detecting device. The casing positions a plurality of components included in the current detecting device in a predetermined positional relationship. The casing is generally composed of an insulating resin material.

### CITATION LIST

### Patent Literature

[Patent Literature 1] Japanese Patent Laid-Open Publication No. 2009-128116

### SUMMARY OF INVENTION

### Technical Problem

However, to attach the conventional current detecting device as disclosed in Patent Literature 1 to a pre-routed wire, such as a bus bar, cumbersome work is required in assembling the magnetoelectric transducer, the magnetic core, and the casing that supports and positions them.

To facilitate attachment to the wire, meanwhile, the current detecting device would have a wire for current detection having terminals in two end portions to be connected to connection ends of a conductive body at pre and post stages of a current transmission path. In this case, the current detecting device is provided in a state in which the magnetic core, the magnetoelectric transducer, the casing that supports and positions the components, and the wire for current detection inserted through the hollow portion of the magnetic core are preassembled.

In a case, however, where the current detecting device having the wire for current detection is employed, the connection ends to be connected to the terminals of the wire for current detection should be provided in advance in the current transmission path. In other words, the current detecting device having the wire for current detection cannot be attached to a wire included in a completed current path.

Furthermore, to enable attachment to a wire included in a completed current path, a bisected magnetic core would be employed. In this case, the current detecting device has a module that supports one bisected piece of the magnetic core and the magnetoelectric transducer, a module that supports the other bisected piece of the magnetic core, and a lock mechanism that fixates both the modules in a combined state.

In a case, however, where the bisected magnetic core is employed, a variation in adhesiveness of the two bisected pieces or positional misalignment of the two bisected pieces leads to deterioration in current detection accuracy. With a smaller cross section of the magnetic core, in particular, the positional misalignment of the two bisected pieces notably affects the current detection accuracy. In order to allow the two bisected pieces of the magnetic core to adhere to each other at a high level of positional accuracy, the current detecting device having the bisected magnetic core thus requires a precise positioning mechanism and a large lock mechanism.

An object of the present invention is to provide a current detecting device that, with a simple configuration, simplifies attachment to a wire included in a completed current path and prevents a variation in currency detection accuracy.

### Solution to Problem

A first aspect of the present invention provides a current detecting device having elements described below:

(1) A first element is a magnetic core having two ends opposite to each other with a gap therebetween and continuously surrounding a hollow portion.

(2) A second element is a magnetoelectric transducer provided in a position of the gap of the magnetic core and detecting a magnetic flux that varies in response to a current passing through the hollow portion of the magnetic core.

(3) A third element is a first module including a core support supporting the magnetic core, and a wire insertion path provided in the position of the gap of the magnetic core and extending from an exterior of the magnetic core to the hollow portion of the magnetic core.

(4) A fourth element is a second module having an outer shape fitting the wire insertion path of the first module and including an element support in an interior thereof supporting the magnetoelectric transducer.

(5) A fifth element is a lock mechanism fixating the second module to the first module in a state where the element support is fitted to the wire insertion path.

A second aspect of the present invention provides an exemplary current detecting device according to the first aspect of the present invention, which includes the core support, the wire insertion path, and the element support each having a configuration described below.

(1-1) The core support is a portion provided in the hollow portion of the magnetic core and provided with a first contact surface and a second contact surface, the first contact surface being brought into contact with a front end portion of the element support, the second contact surface being brought into contact with an inner surface of each of two end portions of the magnetic core and defining a recess with a portion of the element support to which each of the two end portions of the magnetic core is fitted.

(1-2) The wire insertion path is a space extending from the exterior of the magnetic core to the hollow portion of the magnetic core in a state where the two ends of the magnetic core are exposed.

(1-3) The element support is a portion provided with a third contact surface brought into contact with an outer surface of each of the two end portions of the magnetic core and defining a recess with the second contact surface of the core support to which each of the two end portions of the magnetic core is fitted.

A third aspect of the present invention provides an exemplary current detecting device according to the second aspect of the present invention, which includes the element support having a configuration described below. Specifically, the element support according to the third aspect of the present invention has a series of walls including an inner surface defining a hole to which the magnetoelectric transducer fitted and an outer surface serving as the third contact surface.

A fourth aspect of the present invention provides an exemplary current detecting device according to one of the first to third aspects of the present invention, which further includes a connecting mechanism connecting the first module and the second module so as to be movable relative to each other.

A fifth aspect of the present invention provides an exemplary current detecting device according to the fourth aspect of the present invention, which includes the connecting mechanism having a configuration described below. Specifically, the connecting mechanism according to the fifth aspect of the present invention connects the first module and the second module so as to be rotatable relative to each other.

A sixth aspect of the present invention provides an exemplary current detecting device according to the fourth aspect of the present invention, which includes the connecting mechanism having a configuration described below. Specifically, the connecting mechanism according to the sixth aspect of the present invention connects the first module and the second module so as to be rotatable relative to each other around an axis and slidably supports the axis in a linear direction.

A seventh aspect of the present invention provides an exemplary current detecting device according to one of the first to sixth aspects of the present invention, in which a projection along a current path passing through the hollow portion of the magnetic core is provided to at least one of the first module and the second module.

### Advantageous Effects of Invention

In the current detecting device according to the present invention, a wire is inserted into the hollow portion of the magnetic core through the wire insertion path of the first module that supports the magnetic core. Furthermore, in the state where the wire is inserted in the hollow portion of the magnetic core, the element support of the second module is fitted into the wire insertion path of the first module. Thus, the magnetoelectric transducer in the element support is positioned in the gap of the magnetic core. Then, the lock mechanism fixates the second module to the first module, and thus the magnetic core and the magnetoelectric transducer are held in a predetermined positional relationship.

Accordingly, the current detecting device of the present invention can be attached to the wire by simple operations, including insertion of the wire into the hollow portion of the magnetic core, fitting of the element support into the wire insertion path of the first module, and fixation with the lock mechanism. Furthermore, the current detecting device can also be attached to a wire included in a completed current path.

In the current detecting device of the present invention, the magnetic core and the magnetoelectric transducer are positioned at a higher level of accuracy due to the fitting structure of the element support with respect to the wire insertion path. Thus, the current detecting device of the present invention prevents a variation in current detection accuracy. In addition, the lock mechanism of the present invention can be a mechanism simple enough to hold the state where the element support is fitted to the wire insertion path.

In the current detecting device according to the second aspect of the present invention, the core support and the element support define the recesses to which the two end portions of the magnetic core are respectively fitted. In this case, an error in a positional relationship between the magnetic core and the magnetoelectric transducer occurs only due to a dimensional tolerance of a portion of the core support and the element support situated in a very limited range in the vicinity of the two end portions of the magnetic core. Generally, in a molded component, a dimensional tolerance of a portion in a limited range is sufficiently small compared to a dimensional tolerance of a portion over a wide range. Thus, positioning accuracy of the magnetic core and the magnetoelectric transducer is further increased, and thus an effect in preventing a variation in current detection accuracy is further increased.

In the current detecting device according to the third aspect of the present invention, the element support has a series of walls, which include the inner surface that defines the hole to which the magnetoelectric transducer is fitted and the outer surface that serves as the third contact surface brought into contact with each of the end portions of the magnetic core. In this case, the positional relationship between the magnetic core and the magnetoelectric transducer is defined by the thickness of the series of walls surrounding the magnetoelectric transducer. Generally, in a molded component, a dimensional tolerance for thickness in one portion is sufficiently small compared to dimensional tolerances of positions among a plurality of separated portions. Thus, positioning accuracy of the magnetic core and the magnetoelectric transducer is further increased, and thus an effect in preventing a variation in current detection accuracy is further increased.

The current detecting device according to the fourth aspect of the present invention has the connecting mechanism connecting the first module and the second module so as to be movable relative to each other. This facilitates attachment to a wire, compared to a case where the first module and the second module are separated.

In the current detecting device according to the fifth aspect of the present invention, for example, the connecting mechanism connects the two modules so as to be rotatable relative to each other. This allows attachment to the wire with one hand.

In a case where the element support is fitted into the gap of the magnetic core along a circumferential path, the two end portions of the magnetic core need to be chamfered to widen an entrance to the gap of the magnetic core. In the current detecting device according to the sixth aspect of the present invention, the connecting mechanism connects the two modules so as to be rotatable relative to each other around the axis and slidably supports the axis in the linear direction. In this case, the element support of the first module can be fitted along a linear path into the wire insertion path of the second module, specifically the gap of the magnetic core. This facilitates attachment to the wire and eliminates man-hours for chamfering the two end portions of the magnetic core.

In the current detecting device according to the seventh aspect of the present invention, the projection along the current path passing through the hollow portion of the magnetic core is provided to at least one of the first module and the second module. In this case, the current detecting device can be readily fixated to the wire with a bundling tool that bundles the projection and the wire.

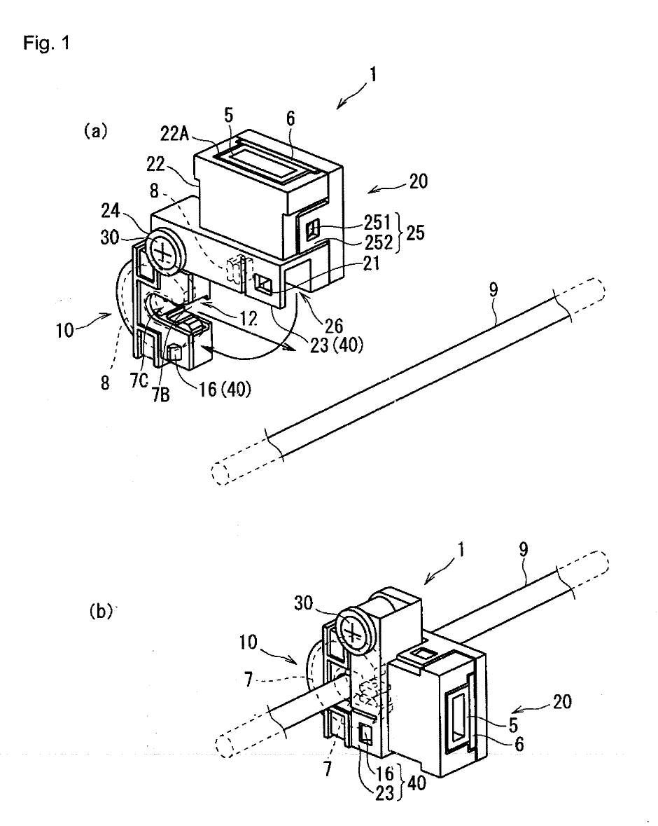

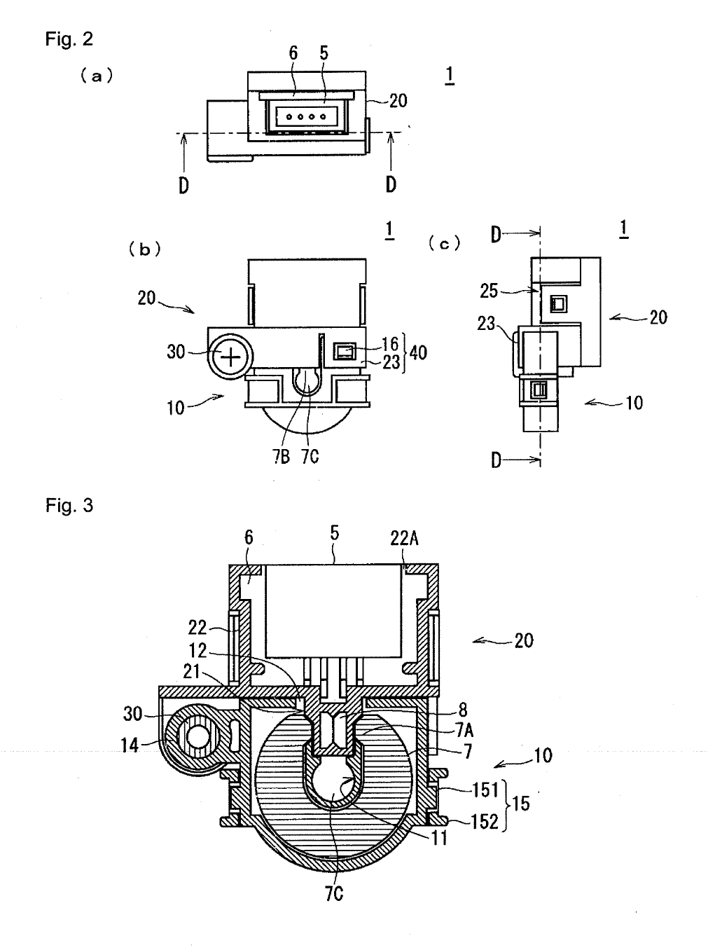

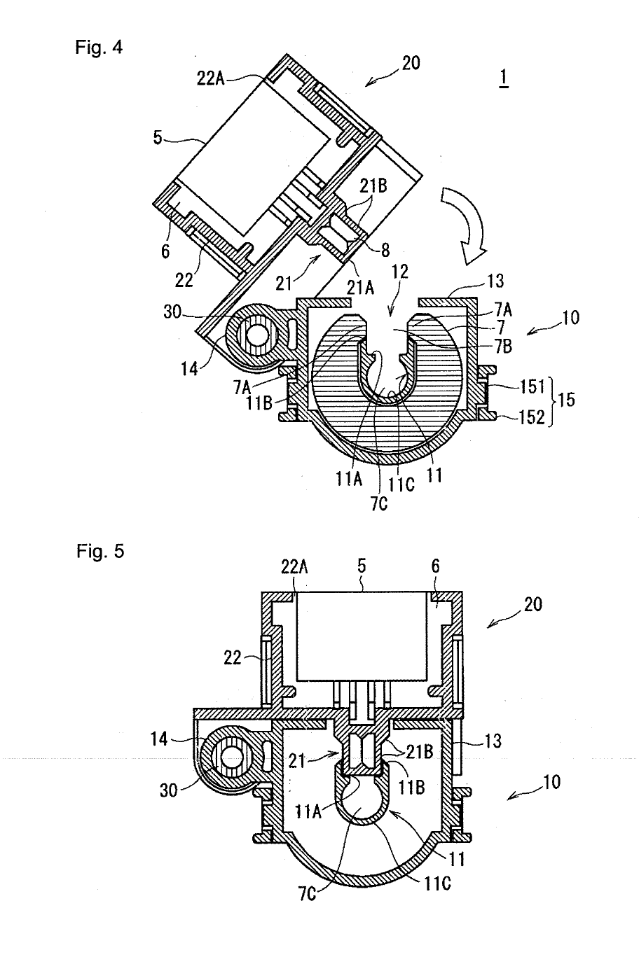

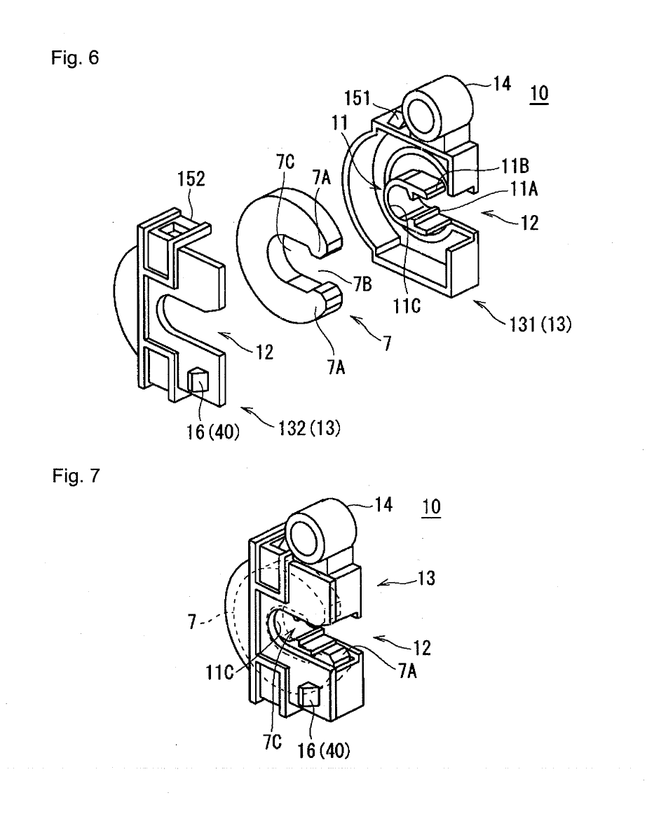

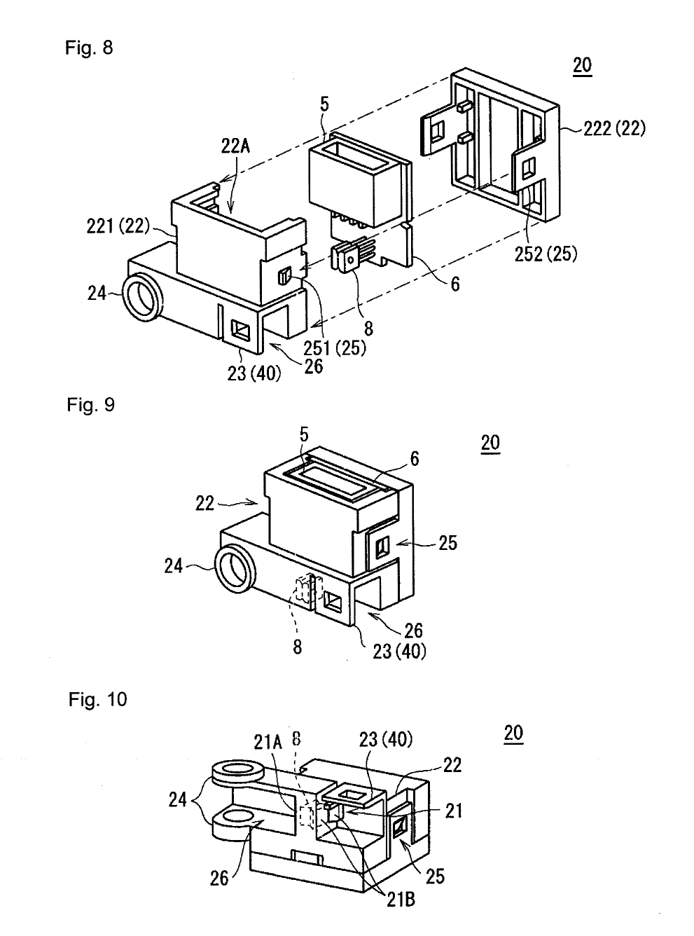

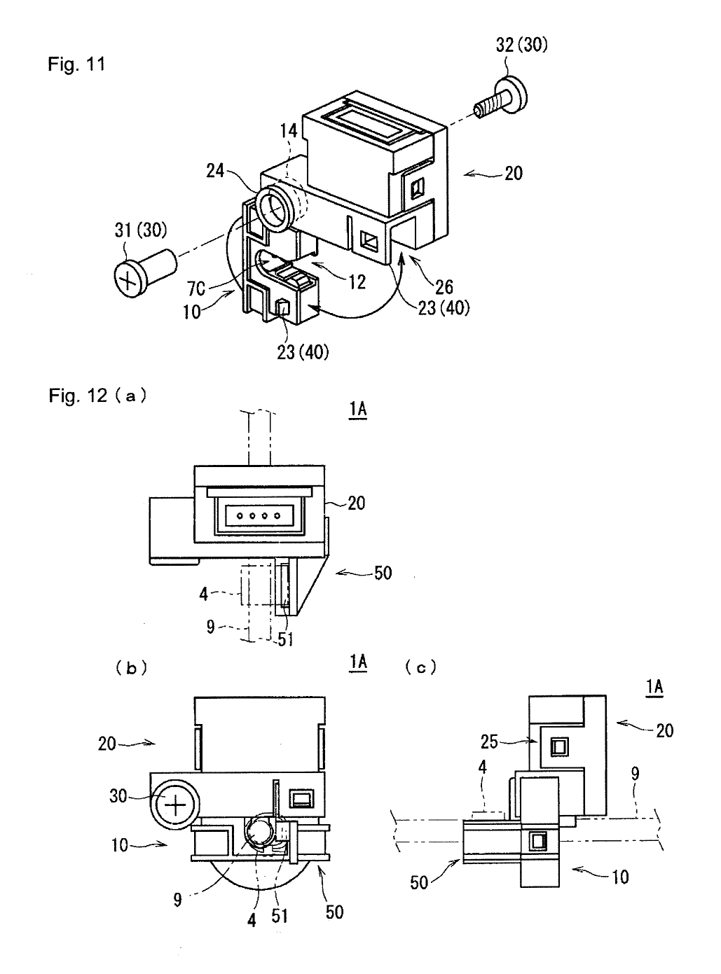

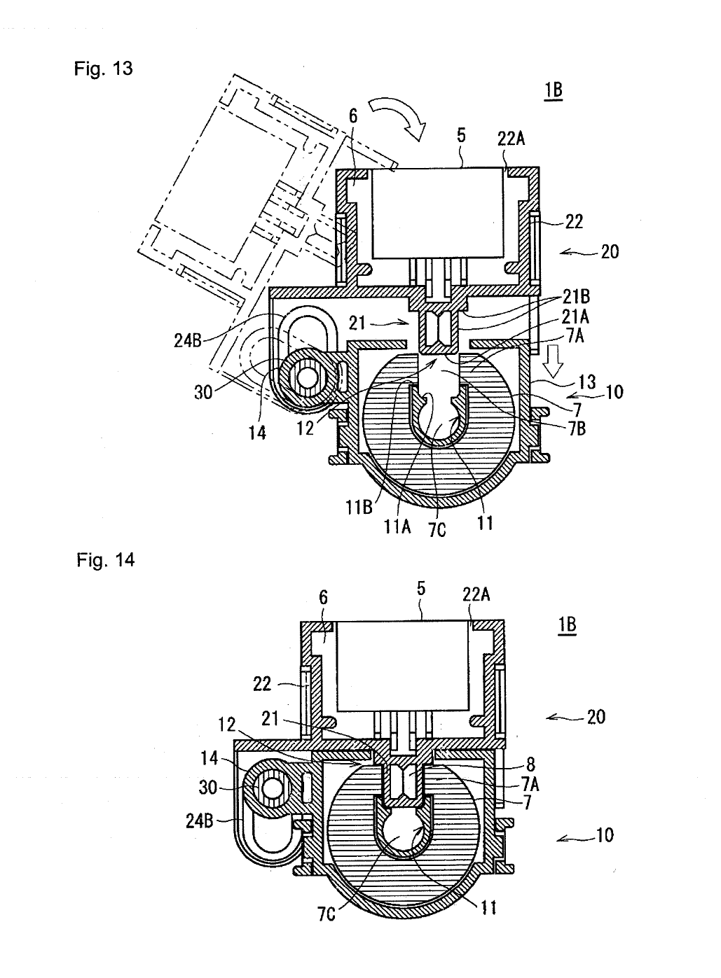

### BRIEF DESCRIPTION OF DRAWINGS

[FIG. 1] Perspective views of a current detecting device 1 according to a first embodiment of the present invention.

[FIG. 2] Views of three sides of the current detecting device 1.

[FIG. 3] A cross-sectional view of the current detecting device 1 in a closed state.

[FIG. 4] A cross-sectional view of the current detecting device 1 in an open state.

[FIG. 5] A cross-sectional view of the current detecting device 1 in the closed state with a magnetic core removed.

[FIG. 6] An exploded perspective view of a core module included in the current detecting device 1.

[FIG. 7] A perspective view of the core module included in the current detecting device 1.

[FIG. 8] An exploded perspective view of an element module included in the current detecting device 1.

[FIG. 9] A perspective view of the element module included in the current detecting device 1 viewed from a first direction.

[FIG. 10] A perspective view of the element module included in the current detecting device 1 viewed from a second direction.

[FIG. 11] A perspective view of two modules and a connecting pin that connects the modules of the current detecting device 1.

[FIG. 12] Views of three sides of a current detecting device 1A according to a second embodiment of the present invention.

[FIG. 13] A cross-sectional view of a current detecting device 1B according to a third embodiment of the present invention in a state before moving to a closed state.

[FIG. 14] A cross-sectional view of the current detecting device 1B in the closed state.

### DESCRIPTION OF EMBODIMENTS

Embodiments of the present invention are described below with reference to the attached drawings. The embodiments below are presented merely as examples of the present invention and shall not be construed as limitations of a technical range of the present invention.

Current detecting devices 1, 1A, and 1B according to the embodiments of the present invention are each a device that detects a current flowing through a wire that electrically connects a battery and a device, such as a motor, in an electric car or a hybrid car.

### First Embodiment

A configuration of the current detecting device 1 according to a first embodiment of the present invention is described below with reference to FIGS. 1 to 11. With reference to FIGS. 1 to 4, the current detecting device 1 has a core module 10, which includes a magnetic core 7; an element module 20, which includes a Hall element 8; and a connecting pin 30 that connects the core module 10 and the element module 20. The core module 10 and the element module 20 are rotatable relative to each other around the connecting pin 30 from an open state in which a gap 7B of the magnetic core 7 is open to a closed state in which the gap 7B is closed.

FIG. 1(a) is a perspective view of the current detecting device 1 in the open state; FIG. 1(b) is a perspective view of the current detecting device 1 in the closed state. In FIG. 1(b), a wire 9 is passed through a hollow portion 7C of the magnetic core 7 supported by the core module 10 in the current detecting device 1. FIGS. 2(a), 2(b), and 2(c) are a plan view, a front view, and a side view, respectively, of the current detecting device 1. FIGS. 3 to 5 are cross-sectional views of a plane D-D shown in FIG. 2.

<Magnetic Core>

The magnetic core 7, which is a magnetic body composed of ferrite or silicon steel, has two ends opposite to each other with the gap 7B of approximately a few mm therebeween and has a continuous shape surrounding the hollow portion 7C. Specifically, the magnetic core 7, along with the narrow gap 7B, forms an annular shape. The magnetic core 7 of the present embodiment, along with the gap 7B, forms an annular shape that surrounds the circular hollow portion 7C. An inner portion and an outer portion of each of two end portions 7A of the magnetic core 7 in the present embodiment are chamfered.

<Hall Element (Magnetoelectric Transducer)>

The Hall element 8, which is disposed in the gap 7B of the magnetic core 7, detects a magnetic flux that varies in response to a current passing through the hollow portion 7C of the magnetic core 7. The Hall element 8 is an example of a magnetoelectric transducer that outputs a magnetic flux detection signal as an electric signal. The Hall element 8 has connection terminals that extend for power input and detection signal output.

The Hall element 8 is disposed such that a predetermined detection center point is positioned at a center point of the gap 7B of the magnetic core 7 and such that front and rear surfaces thereof are orthogonal to a direction of a magnetic flux generated in the gap 7B. Ideally, the detection center point of the Hall element 8 is positioned on a line connecting the centers of projection planes of the opposing two end portions of the magnetic core 7.

<Electronic Board>

An electronic board 6 is a printed circuit board on which the Hall element 8 is mounted through the connection terminals. In addition to the Hall element 8, the electronic board 6 has a circuit and a connector 5, the circuit performing processing, such as amplification, on the magnetic flux detection signal output from the Hall element 8.

A mating connector on a wire (not shown in the drawing) is connected to the connector 5. Furthermore, the electronic board 6 has a circuit that electrically connects the Hall element 8 and a terminal of the connector 5. For instance, the electronic board 6 has a circuit that supplies power to the Hall element 8, the power being input externally through a wire and the connector 5; and a circuit that amplifies a detection signal of the Hall element 8 and outputs the amplified signal to the terminal of the connector 5. Thus, the current detecting device 1 outputs a current detection signal to an external circuit, such as an electronic control unit, through a wire having a connector connected to the connector 5.

<Core Module>

With reference to FIGS. 3, 4, and 6, the core module 10 includes the magnetic core 7 and a core casing 13 that accommodates the magnetic core 7. The core casing 13, which is an insulating member, includes a first main case 131 and a first cover 13.2 attached to the first main case 131. Each of the first main case 131 and the first cover 132 is an integrally formed member composed of an insulating resin, such as, for example, polyamide (PA), polypropylene (PP), or an ABS resin.

The first cover 132 is attached to the first main case 131 that accommodates the magnetic core 7 so as to cover an opening of the first main case 131 while holding the magnetic core 7 therein. With reference to FIGS. 6 and 7, the first main case 131 and the first cover 132 hold and accommodate the magnetic core 7 therebetween in a state where the two end portions 7A of the magnetic core 7 are exposed to an exterior. The magnetic core 7 is held between the first main case 131 and the first cover 132, and thus a position in a current passing direction in the core casing 13 is kept constant.

Furthermore, the first main case 131 and the first cover 132 have a first lock mechanism 15, which holds the components in a combined state. The first lock mechanism 15, as shown in FIGS. 6 and 7, has a hook 151 and a frame 152, the hook 151 projecting from a side surface of the first main case 131, the frame 152 having an annular shape on a side of the first cover 132. The hook 151 of the first main case 131 is snapped into a hole defined by the frame 152 of the first cover 132, and thus the first main case 131 and the first cover 132 are held in the combined state.

In addition, the core casing 13 has a wire insertion path 12 extending from an exterior of the magnetic core 7 to the hollow portion 7C of the magnetic core 7 in a position of the gap 7B of the magnetic core 7. With reference to FIGS. 1(a), 4, and 7, the wire insertion path 12 in the present embodiment is a space that extends from the exterior of the magnetic core 7 to the hollow portion 7C of the magnetic core 7 in a state where the two end portions 7A of the magnetic core 7 are exposed.

Furthermore, the core casing 13 of the core module 10 has a core support 11 and a first connector 14, the core support 11 supporting the magnetic core 7 from within in a position of the hollow portion 7C of the magnetic core 7, the first connector 14 having a through-hole through which the connecting pin 30 is passed.

With reference to FIGS. 3 and 4, the core support 11 is provided in the hollow portion 7C of the magnetic core 7 and has a continuous wall shape along a shape of the hollow portion 7C of the magnetic core 7 with an opening in a direction of the gap 7B. Specifically, the wall of the core support 11 is open in the portion of the wire insertion path 12. The core support 11 serves as a separation wall that electrically insulates the magnetic core 7 from the wire 9 passed through the hollow portion 7C and prevents foreign substances, such as water or dust, from entering the core casing 13.

<Element Module>

With reference to FIGS. 3, 4, and 8, the element module 20 includes the Hall element 8, the electronic board 6 on which the Hall element 8 and the connector 5 are mounted, and an element casing 22 that accommodates the Hall element 8 and the electronic board 6. The element casing 22, which is an insulating member, includes a second main case 221 and a second cover 222 attached to the second main case 221. Each of the second main case 221 and the second cover 222 is an integrally formed member composed of an insulating resin, such as, for example, polyamide (PA), polypropylene (PP), or an ABS resin.

The second cover 222 is attached to the second main case 221 that accommodates the Hall element 8 and the electronic board 6 so as to cover an opening of the second main case 221 while holding therein the Hall element 8, the connector 5, and the electronic board 6. With reference to FIGS. 8 to 10, the second main case 221 and the second cover 222 hold and accommodate therebetween the Hall element 8, the connector 5, and the electronic board 6 in a state where a connection end of the connector 5 is exposed to an exterior. The Hall element 8 is held between the second main case 221 and the second cover 222, and thus a position in a current passing direction in the element casing 22 is kept constant.

Furthermore, the second main case 221 and the second cover 222 have a second lock mechanism 25, which holds the components in a combined state. The second lock mechanism 25 shown in FIGS. 8 to 10 has a hook 251 and a frame 252, the hook 251 projecting from a side surface of the second main case 221, the frame 252 having an annular shape on a side of the second cover 222. The hook 251 of the second main case 221 is snapped into a hole defined by the frame 252 of the second cover 222, and thus the second main case 221 and the second cover 222 are held in the combined state.

Furthermore, the element casing 22 of the element module 20 has an element support 21 supporting the Hall element 8 and a second connector 24 having a through-hole through which the connecting pin 30 is passed. The element support 21 has a shape that fits the wire insertion path 12 of the core module 10 and supports the Hall element 8 inside the element support 21.

<Connecting Mechanism>

The first connector 14 of the core module 10, the second connector 24 of the element module 20, and the connecting pin 30 constitute a connecting mechanism connecting the core module 10 and the element module 20 so as to be rotatable relative to each other. FIG. 11 is a perspective view of the two modules 10 and 20 and the connecting pin 30 that connects the modules of the current detecting device 1.

The connecting pin 30 is a shaft that connects the core module 10 and the element module 20. With reference to FIG. 11, the connecting pin 30 includes a screw receiving pin 31 having a tapped hole in a shaft and a screw 32 screwed into the tapped hole in the screw receiving pin 31. The screw receiving pin 31 and the screw 32 are inserted and connected through the respective through-holes from the sides of the first connector 14 and the second connector 24 which are aligned to each other.

The core module 10 and the element module 20 connected by the connecting pin 30 are rotatable relative to each other around the connecting pin 30 from the open state in which the gap 7B of the magnetic core 7 is open to the closed state in which the gap 7B is closed. Being “rotatable relative to each other” means that the element module 20 is rotatable relative to the core module 10 and that the core module 10 is rotatable relative to the element module 20.

<Positioning Structure of Magnetic Core and Hall Element>

With reference to FIGS. 3, 4, and 6, the core support 11 of the core module 10 has a first contact surface 11A and a second contact surface 11B. The first contact surface 11A is brought into contact with a front end surface 21A of the element support 21 in the element module 20. The second contact surface 11B is brought into contact with an inner surface of each of the two end portions 7A of the magnetic core 7.

With reference to FIGS. 3, 4, and 10, the element support 21 of the element module 20 has inner surfaces composed of a series of walls that define a hole to which the Hall element 8 is fitted. Specifically, the element support 21 has a continuous wall shape surrounding the Hall element 8. FIG. 10 illustrates an external appearance of the element support 21.

The element support 21 of the element module 20 also has a third contact surface 21B on an outer surface thereof, the third contact surface 21B being brought into contact with an outer surface of each of the two end portions 7A of the magnetic core 7. The outer surface of each of the two end portions 7A of the magnetic core 7 indicates a surface of each of the two end portions 7A of the magnetic core 7 positioned outside relative to a surface brought into contact with the second contact surface 11B of the element support 21.

FIG. 5 is a cross-sectional view along D-D of the current detecting device 1 in the closed state with the magnetic core 7 removed. With reference to FIGS. 3 and 5, in the closed state where the element support 21 is fitted to the wire insertion path 12 of the core module 10, the second contact surfaces 11B on the exterior of the core support 11 and the third contact surfaces 21B on the exterior of the element support 21 are combined with each other to define two recesses to which the two end portions 7A of the magnetic core 7 are respectively fitted.

The two end portions 7A of the magnetic core 7 are symmetrical with reference to the center of the gap 7B. Thus, the two recesses defined by the second contact surfaces 11B of the core support 11 and the third contact surfaces 21B of the element support 21 are also symmetrical with reference to the center of the gap 7B.

In the current detecting device 1, the wire 9 is inserted into the hollow portion 7C of the magnetic core 7 through the wire insertion path 12 of the core module 10 that supports the magnetic core 7. In the state where the wire 9 is inserted in the hollow portion 7C of the magnetic core 7, the clement module 20 is rotated relative to the core module 10 from the open state to the closed state. Thus, the element support 21 of the element module 20 is fitted into the wire insertion path 12 of the core module 10 and the Hall element 8 in the element support 21 is positioned in the gap 7B of the magnetic core 7.

The element casing 22 has a groove 26 to which a portion of the core casing 13 is fitted when the element module 20 is rotated relative to the core module 10 from the open state to the closed state. The core module 10 and the element module 20 are held in a constant relationship in the current passing direction due to the fitting structure of the portion of the core casing 13 and the groove 26 of the element casing 22.

<Lock Mechanism>

The core casing 13 of the core module 10 and the element casing 22 of the element module 20 have a third lock mechanism 40, which fixates the element module 20 to the core module 10 in the state where the element support 21 is fitted to the wire insertion path 12. The third lock mechanism 40, as shown in FIGS. 1 and 2, has a hook 16 and a frame 23, the hook 16 projecting from a surface of the core casing 13, the frame 23 having an annular shape on the element casing 22.

In the current detecting device 1, simply rotating the element module 20 from the open state to the closed state completes the fitting of the element support 21 to the wire insertion path 12 of the core module 10 and the fixation of both the modules 10 and 20 by the third lock mechanism 40. The third lock mechanism 40 fixates the element module 20 to the core module 10, and thus the magnetic core 7 and the Hall element 8 are held in a predetermined positional relationship. Incidentally, the hook 16 may be provided to the element casing 22 and the frame 23 may be provided to the core casing 13.

<Effects>

As described above, the current detecting device 1 can be attached to the wire 9 by simple operations, including insertion of the wire 9 into the hollow portion 7C of the magnetic core 7 and rotation of the element module 20. Furthermore, the current detecting device 1 can also be attached to the wire 9 included in a completed current path.

In the current detecting device 1, the magnetic core 7 and the Hall element 8 are positioned at a higher level of accuracy due to the fitting structure of the element support 21 to the wire insertion path 12. Thus, the current detecting device 1 prevents a variation in current detection accuracy. In addition, the third lock mechanism 40 can be a mechanism simple enough to hold the state where the element support 21 is fitted to the wire insertion path 12.

With reference to FIGS. 3 and 5, the core support 11 and the element support 21 define the recesses to which the two end portions 7A of the magnetic core 7 are respectively fitted in the current detecting device 1. According to this configuration, an error in the positional relationship between the magnetic core 7 and the Hall element 8 occurs only due to a dimensional tolerance of a portion of the core support 11 and the element support 21 situated in a very limited range in the vicinity of the two end portions 7A of the magnetic core 7.

Generally, in a molded component, a dimensional tolerance of a portion in a limited range is sufficiently small compared to a dimensional tolerance of a portion over a wide range. Thus, in the current detecting device 1, the magnetic core 7 and the Hall element 8 are positioned at a high level of accuracy and a variation in current detection accuracy is small.

In the current detecting device 1, the element support 21 has a series of walls, which include the inner surfaces that define a hole to which the Hall element 8 is fitted and the outer surfaces that serve as the third contact surfaces 21B brought into contact with the two end portions 7A of the magnetic core 7. According to this configuration, the positional relationship between the magnetic core 7 and the Hall element 8 is defined by the thickness of the series of walls surrounding the Hall element 8. Generally, in a molded component, a dimensional tolerance for thickness in one portion is sufficiently small compared to dimensional tolerances of positions among a plurality of separated portions. This configuration also increases a level of positioning accuracy of the magnetic core 7 and the Hall element 8 in the current detecting device 1 and reduces a variation in current detection accuracy.

In the current detecting device 1, the core module 10 and the element module 20 are rotatably connected by the connecting mechanism 14, 24, 30. This allows attachment of the current detecting device 1 to the wire 9 with one hand, thus facilitating attachment compared to a case where both the modules 10 and 20 are separated.

### Second Embodiment

A current detecting device 1A according to a second embodiment of the present invention is described below with reference to views of three sides shown in FIG. 12. The current detecting device 1A has a configuration in which a projection 50 for fixation to the wire 9 is added to the current detecting device 1 shown in FIGS. 1 to 12. In FIG. 12, components which are the same as those shown in FIGS. 1 to 11 are denoted with the same reference numerals. Only differences from the current detecting device 1 in the current detecting device 1A are described below.

The core casing 13 of the core module 10 in the current detecting device 1A has the projection 50 along a current path, specifically the wire 9, passing through the hollow portion 7C of the magnetic core 7. The projection 50 is used for fixating the current detecting device 1A with a bundling band 4 to the wire 9 passed through the hollow portion 7C of the magnetic core 7. Thus, the projection 50 has a through-hole 51 through which the bundling band 4 is passed. In FIG. 12, the wire 9 and the bundling band 4 are drawn by a virtual line (dashed-two dotted line).

The projection 50 for fixation to the wire 9 facilitates fixation of the current detecting device 1A to the wire 9. Alternatively, the current detecting device 1A may have the projection 50 without the through-hole 51. In this case, the current detecting device 1A is fixated to the wire 9 with an adhesive tape that bundles the wire 9 and the projection 50.

In the current detecting device 1A, the projection 50 is provided to at least one of the core module 10 and the element module 20.

### Third Embodiment

A current detecting device 1B according to a third embodiment of the present invention is described below with reference to FIGS. 13 and 14. The current detecting device 1B is different from the current detecting device 1 shown in FIGS. 1 to 12 in a configuration of a connecting mechanism movably connecting the two modules 10 and 20. In FIGS. 13 and 14, components which are the same as those shown in FIGS. 1 to 11 are denoted with the same reference numerals. Only differences from the current detecting device 1 in the current detecting device 1B are described below.

The connecting mechanism of the current detecting device 1B connects the core module 10 and the element module 20 so as to be rotatable relative to each other around a connecting pin 30 and slidably supports the connecting pin 30 in a linear direction.

More specifically, the connecting mechanism of the current detecting device 1B has a first connector 14 provided in the core casing 13, a second connector 24B provided in the element casing 22, and the connecting pin 30. The first connector 14 has a circular through-hole tightly in contact with an outer peripheral surface of the connecting pin 30. The second connector 24B has an elongated through-hole having a short diameter tightly in contact with the outer peripheral surface of the connecting pin 30. The screw receiving pin 31 and the screw 32 included in the connecting pin 30 are inserted and connected through the respective through-holes from the sides of the first connector 14 and the second connector 24 which are aligned to each other.

In the current detecting device 1B, the core module 10 is rotatable around the connecting pin 30, which is a shaft. Meanwhile, the element module 20 is rotatable around the connecting pin 30, which is a shaft, and is linearly slidable in a direction of a long diameter of the through-hole in the second connector 24B.

With reference to FIG. 13, in the current detecting device 1A, the element module 20 is first rotated, and then the element support 21 is moved to a position facing the wire insertion path 12 from the front. Subsequently, the element module 20 is linearly slid toward the core module 10, thus fitting the element support 21 into the wire insertion path 12 of the core module 10 and fixating both the modules 10 and 20 with the third lock mechanism 40. The third lock mechanism 40 fixates the element module 20 to the core module 10, and thus the magnet core 7 and the Hall element 8 are held in a predetermined positional relationship.

Similar to the current detecting device 1, the core support 11 in the current detecting device 1A also has the first contact surface 11A and the second contact surface 11B, the first contact surface 11A being brought into contact with the front end surface 21A of the element support 21 of the element module 20, the second contact surface 11B being brought into contact with an inner surface of each of the two end portions 7A of the magnetic core 7. Similar to the current detecting device 1, the element support 21 in the current detecting device 1A also has the third contact surface 21B on the outer surface thereof, the third contact surface 21B being brought into contact with the outer surface of each of the two end portions 7A of the magnetic core 7.

With reference to FIG. 14, in the closed state where the element support 21 is fitted to the wire insertion path 12 of the core module 10, the second contact surfaces 11B on the exterior of the core support 11 and the third contact surfaces 21B on the exterior of the element support 21 are combined with each other to define two recesses to which the two end portions 7A of the magnetic core 7 are respectively fitted.

In the current detecting device 1 according to the first embodiment, the element support 21 is fitted into the gap 7B of the magnetic core 7 along a circumferential path. In order to widen an entrance to the gap 7B of the magnetic core 7, the two end portions 7A of the magnetic core 7 need to be chamfered.

Meanwhile, the connecting mechanism of the current detecting device 1A connects the two modules 10 and 20 so as to be rotatable relative to each other and slidably supports the connecting pin 30 in the linear direction. Thus, the element support 21 of the element module 20 can be fitted along a linear path into the wire insertion path 12 of the core module 10, specifically the gap 7B of the magnetic core 7. Accordingly, attachment to the wire 9 can be readily performed with one hand. Furthermore, man-hours for chamfering the two end portions 7A of the magnetic core 7 can be eliminated.

<Miscellaneous>

In the current detecting device 1B, the connecting mechanism may also movably support the two modules 10 and 20 only in the linear direction. In this case, the connecting pin 30 has a rectangular column shape, for example. The through-hole in the second connector 24B is formed into an elongated shape having a length sufficient to separate the two modules 10 and 20 at a distance greater than the diameter of the wire 9.

The current detecting devices 1 and 1A may have a configuration in which the connecting mechanism of the two modules 10 and 20 is eliminated and the two modules 10 and 20 are provided separately. In this case, however, attachment to the wire 9 with one hand is difficult.

### REFERENCE SIGNS LIST

1, 1A, 1B: Current detecting device

4: Bundling band

5: Connector

6: Electronic board

7: Magnetic core

7A: End portion of magnetic core

7C: Hollow portion of magnetic core

7B: Gap of magnetic core

8: Hall element

9: Wire

10: Core module

21: Core support

11A: First contact surface of core support

11B: Second contact surface of core support

12: Wire insertion path

13: Core casing

14: First connector (connecting mechanism)

15: First lock mechanism

16: Hook

20: Element module

21: Element support

21A: Front end surface of element support

21B: Third contact surface of element support

22: Element casing

24, 24B: Second connector (connecting mechanism)

25: Second lock mechanism

26: Groove of element casing

30: Connecting pin (connecting mechanism)

31: Screw receiving pin

32: Screw

40: Third lock mechanism

50: Projection

51: Through-hole

131: First main case

132: First cover

221: Second main case

222: Second cover

1. A current detecting device comprising:
a magnetic core having two ends opposite to each other with a gap therebetween and continuously surrounding a hollow portion;
a magnetoelectric transducer provided in a position of the gap of the magnetic core and detecting a magnetic flux that varies in response to a current passing through the hollow portion of the magnetic core;
a first module comprising:
a core support supporting the magnetic core; and
a wire insertion path provided in the position of the gap of the magnetic core and extending from an exterior of the magnetic core to the hollow portion of the magnetic core;
a second module having an outer shape fitting the wire insertion path of the first module and comprising:
an element support in an interior thereof supporting the magnetoelectric transducer; and
a lock mechanism fixating the second module to the first module in a state where the element support is fitted to the wire insertion path in contact with a surface on an exterior of each of two end portions of the magnetic core.

2. The current detecting device according to claim 1, wherein
the core support is a portion provided in the hollow portion of the magnetic core and provided with a first contact surface and a second contact surface, the first contact surface being brought into contact with a front end portion of the element support, the second contact surface being brought into contact with an inner surface of each of two end portions of the magnetic core and defining a recess with a portion of the element support to which each of the two end portions of the magnetic core fitted,
the wire insertion path is a space extending from the exterior of the magnetic core to the hollow portion of the magnetic core in a state where the two ends of the magnetic core are exposed, and
the element support is a portion provided with a third contact surface brought into contact with an outer surface of each of the two end portions of the magnetic core and defining a recess with the second contact surface of the core support to which each of the two end portions of the magnetic core is fitted.

3. The current detecting device according to claim 2, wherein the element support has a series of walls including an inner surface defining a hole to which the magnetoelectric transducer is fitted and an outer surface serving as the third contact surface.

4. The current detecting device according to claim 1, further comprising:
a connecting mechanism connecting the first module and the second module so as to be movable relative to each other.

5. The current detecting device according to claim 4, wherein the connecting mechanism connects the first module and the second module so as to be rotatable relative to each other.

6. The current detecting device according to claim 4, wherein the connecting mechanism connects the first module and the second module so as to be rotatable relative to each other around an axis and slidably supports the axis in a linear direction.

7. The current detecting device according to claim 1, wherein a projection along a current path passing through the hollow portion of the magnetic core is provided to at least one of the first module and the second module.
